(19) United States
(12) Patent Application Publication
(10) Pub. No.: US 2015/0077143 A1
(43) Pub. Date: Mar. 19, 2015

(54) APPARATUS FOR TESTING RESISTIVITY OF SEMICONDUCTOR AND METHOD FOR TESTING RESISTIVITY OF SEMICONDUCTOR

(71) Applicant: Kabushiki Kaisha Toshiba, Minato-ku (JP)

(72) Inventor: Akira MAEKAWA, Kanagawa-ken (JP)

(73) Assignee: Kabushiki Kaisha Toshiba, Minato-ku (JP)

(21) Appl. No.: 14/207,996

(22) Filed: Mar. 13, 2014

(30) Foreign Application Priority Data
Sep. 19, 2013 (JP) 2013-194311

(51) Int. Cl. G01R 27/02; G01N 21/47

(52) U.S. Cl. CPC G01R 27/02; G01N 21/47
USPC 324/693

(57) ABSTRACT

According to one embodiment, an apparatus is configured to test a resistivity of a semiconductor formed on a matrix. The apparatus includes: a first and a second choppers; an irradiation unit; a detector; a first ans a second lock-in amplifiers; and a computer. The first lock-in amplifier is configured to detect a signal with the first chopping frequency out of a signal transmitted from the detector. The second lock-in amplifier is configured to detect a signal with the second chopping frequency out of a signal transmitted from the detector. The computer is configured to estimate a ratio between a reflectance of the infrared light with the first wavelength out of the reflected light and a reflectance of the infrared light with the second wavelength out of the reflected light on the basis of signals transmitted from the first lock-in amplifier and the second lock-in amplifier.

### CROSS-REFERENCE TO RELATED APPLICATIONS

This application is based upon and claims the benefit of priority from Japanese Patent Application No. 2013-194311, filed on Sep. 19, 2013; the entire contents of which are incorporated herein by reference.

### FIELD

Embodiments described herein relate generally to a apparatus for testing resistivity of semiconductor and a method for testing resistivity of semiconductor.

### BACKGROUND

Methods for testing the resistivity of a semiconductor include electrical test methods such as the four-point probe method and C-V measurement, for example. However, the electrical test methods require a relatively long measurement time. In addition, they need destructive measurement in which an object to be measured is processed to prepare a measurement sample, like electrode formation or the like, for example.

Other test methods include optical test methods such as Fourier transform infrared spectroscopy (FT-IR) and ellipsometry, for example. Such optical test methods use infrared light emitted from a lamp light source. However, in the optical test methods using a lamp, although non-destructive measurement is possible, measurement accuracy is low as compared to the measurement accuracy of the electrical test methods.

### BRIEF DESCRIPTION OF THE DRAWINGS

FIG. 1 is a block diagram showing an apparatus for testing a resistivity of a semiconductor according to an embodiment of the invention;

FIG. 2 is a graph illustrating an example of a relationship between an wavelength and a reflectance of reflected light reflected at SiC (silicon carbide);

FIG. 3 is a block diagram showing another apparatus for testing a resistivity of a semiconductor according to an embodiment of the invention;

FIG. 4A and FIG. 4B are schematic diagrams showing signals outputted by a detector and a first lock-in amplifier;

FIG. 5 is a block diagram showing still another apparatus for testing a resistivity of a semiconductor according to an embodiment of the invention;

FIG. 6 is a flow chart showing a method for testing a resistivity of a semiconductor according to an embodiment of the invention; and

FIG. 7 is a flow chart showing another method for testing a resistivity of a semiconductor according to an embodiment.

### DETAILED DESCRIPTION

In general, according to one embodiment, an apparatus for testing the resistivity of a semiconductor configured to test a resistivity of a semiconductor formed on a matrix. The apparatus includes: a first chopper configured to chop infrared light with a first wavelength emitted from a first light source at a first chopping frequency, the first wavelength being a wavelength between a transverse optical phonon frequency and a longitudinal optical phonon frequency; a second chopper configured to chop infrared light with a second wavelength emitted from a second light source at a second chopping frequency, the second wavelength being a wavelength different from the first wavelength; an irradiation unit configured to cause synthetic light produced by synthesizing the infrared light with the first wavelength and the infrared light with the second wavelength together to be applied to the semiconductor; a detector configured to detect an intensity of reflected light of the synthetic light reflected at the semiconductor; a first lock-in amplifier configured to detect a signal with the first chopping frequency out of a signal transmitted from the detector; a second lock-in amplifier configured to detect a signal with the second chopping frequency out of a signal transmitted from the detector; and a computer configured to estimate a ratio between a reflectance of the infrared light with the first wavelength out of the reflected light and a reflectance of the infrared light with the second wavelength out of the reflected light on the basis of signals transmitted from the first lock-in amplifier and the second lock-in amplifier.

Hereinbelow, embodiments of the invention are described with reference to the drawings. In the drawings, like components are marked with the same reference numerals, and a detailed description is omitted as appropriate.

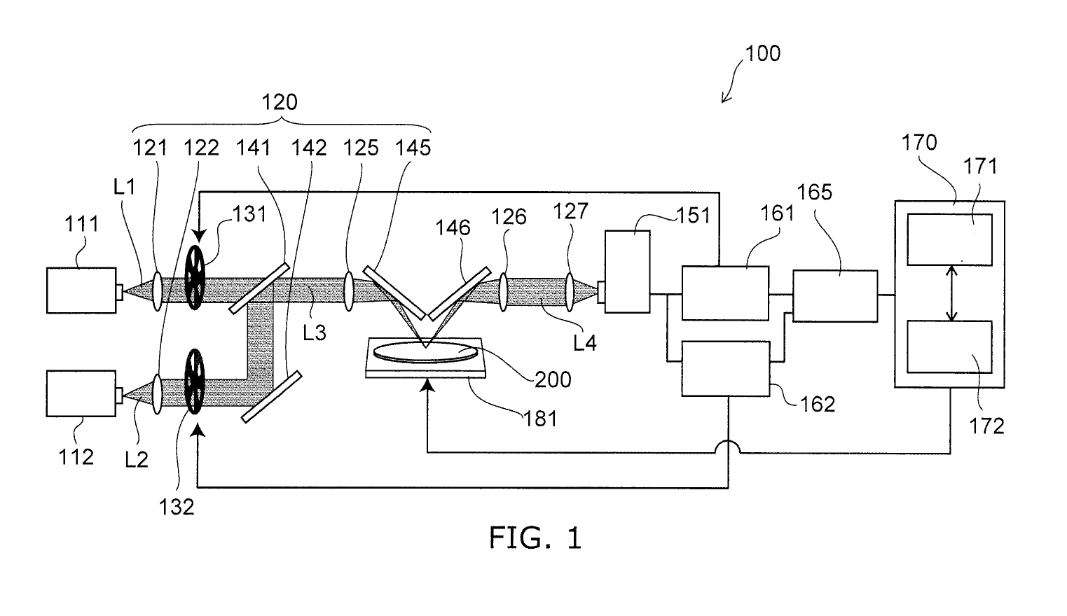

FIG. 1 is a block diagram showing an apparatus for testing the resistivity of a semiconductor according to an embodiment of the invention.

The apparatus for testing the resistivity of a semiconductor according to the embodiment tests the resistivity of a semiconductor formed on a matrix (for example, a semiconductor wafer). An apparatus for testing the resistivity of a semiconductor 100 shown in FIG. 1 includes a first light source 111, a second light source 112, a first chopper 131, a second chopper 132, an irradiation unit 120, a detector 151, a first lock-in amplifier 161, a second lock-in amplifier 162, a signal processing device 165, a computer 170, and a stage 181.

The irradiation unit 120 of the apparatus for testing the resistivity of a semiconductor 100 shown in FIG. 1 includes a first lens 121, a second lens 122, a first dichroic mirror 141, a second dichroic mirror 142, a third lens 125, and a third dichroic mirror 145. The apparatus for testing the resistivity of a semiconductor 100 shown in FIG. 1 includes a fourth lens 126, a fifth lens 127, and a fourth dichroic mirror 146 as appropriate. The installation configuration of the lenses and the dichroic mirrors is not limited to the installation configuration shown in FIG. 1 but may be altered as appropriate. The second dichroic mirror 142 is not limited to a dichroic mirror, and any mirror capable of reflecting infrared light L2 may be used, for example. The third dichroic mirror 145 is not limited to a dichroic mirror, and any mirror capable of reflecting infrared light L3 in which infrared light L1 and infrared light L2 are synthesized with each other may be used, for example. The fourth dichroic mirror 146 is not limited to a dichroic mirror, and any mirror capable of reflecting reflected light L4 reflected at a semiconductor of a sample 200 may be used, for example.

The apparatus for testing the resistivity of a semiconductor 100 according to the embodiment may not necessarily include the first light source 111 and the second light source 112.

The first light source 111 is a semiconductor laser such as a quantum cascade laser, for example, and emits infrared light L1 of a single wavelength λ1. The second light source 112 is a semiconductor laser such as a quantum cascade laser, for example, and emits infrared light L2 of a single wavelength λ2.

The wavelength λ1 of the infrared light L1 emitted by the first light source 111 is different from the wavelength λ2 of the infrared light L2 emitted by the second light source 112. The wavelength of each of the infrared light L1 and the infrared light L2 is approximately 8 micrometers (μm), approximately 10 μm, approximately 12 μm, or approximately 14 μm, for example.

The first chopper 131 opens and closes the infrared light L1 emitted from the first light source 111 at a prescribed frequency (chopping frequency). That is, the first chopper 131 produces a light quantity change in accordance with the chopping frequency by periodically chopping the infrared light L1 emitted from the first light source 111.

The second chopper 132 opens and closes the infrared light L2 emitted from the second light source 112 at a prescribed frequency (chopping frequency). That is, the second chopper 132 produces a light quantity change in accordance with the chopping frequency by periodically chopping the infrared light L2 emitted from the second light source 112.

The chopping frequency f1 of the first chopper 131 is different from the chopping frequency f2 of the second chopper 132. One of the chopping frequency f1 and the chopping frequency f2 is not an integral multiple of the other of the chopping frequency f1 and the chopping frequency f2. The chopping frequency f1 of the first chopper 131 is approximately 30 kilohertz (kHz), for example. The chopping frequency f2 of the second chopper 132 is approximately 50 kHz, for example. However, the chopping frequency f1 of the first chopper 131 and the chopping frequency f2 of the second chopper 132 are not limited thereto.

In the apparatus for testing the resistivity of a semiconductor 100 shown in FIG. 1, the irradiation unit 120 synthesizes the infrared light L1 emitted from the first light source 111 and the infrared light L2 emitted from the second light source 112 together, and applies the synthesized infrared light (synthetic light) to a prescribed range of a sample 200. Specifically, the first lens 121, the first dichroic mirror 141, the third lens 125, and the third dichroic mirror 145 cause the infrared light L1 emitted from the first light source 111 to be applied to the prescribed range of the sample 200. The second lens 122, the second dichroic mirror 142, the first dichroic mirror 141, the third lens 125, and the third dichroic mirror 145 cause the infrared light L2 emitted from the second light source 112 to be applied to the prescribed range of the sample 200.

At this time, the infrared light L1 that has passed through the first dichroic mirror 141 and the infrared light L2 reflected at the first dichroic mirror 141 are synthesized with each other. The infrared light L3 (synthetic light) in which the infrared light L1 and the infrared light L2 are synthesized with each other is applied to the prescribed range of the sample 200 coaxially. That is, the infrared light L3 having a plurality of wavelengths is applied to the prescribed range of the sample 200 coaxially.

The sample 200 includes a semiconductor to be tested and a matrix. The semiconductor to be tested is formed on the surface of the matrix. The semiconductor to be tested is formed on the surface of the matrix by epitaxial growth, for example. The sample 200 is mounted on the stage 181. The stage 181 can move in the horizontal direction on the basis of a signal transmitted from the computer 170.

The reflected light L4 reflected at the semiconductor of the sample 200 is reflected at the fourth dichroic mirror 146, and passes through the fourth lens 126 and the fifth lens 127 to be guided to the detector 151. The detector 151 detects the reflected light L4 reflected at the semiconductor of the sample 200. The detector 151 outputs a voltage signal corresponding to the intensity of the reflected light L4 (detected signal) to the first lock-in amplifier 161 and the second lock-in amplifier 162, for example.

The first lock-in amplifier 161 detects and amplifies a signal with the chopping frequency f1 of the first chopper 131. In other words, the first lock-in amplifier 161 extracts only a component that changes at the chopping frequency f1 of the first chopper 131. Thereby, the first lock-in amplifier 161 can perform signal detection with higher accuracy by detecting a small signal in the signal (input signal) transmitted from the detector 151. Thus, the signal (reference signal) with the frequency transmitted from the first chopper 131 acts on a given signal; thereby, based on the input signal and the reference signal, the first lock-in amplifier 161 detects the amplitude information of the given signal.

The second lock-in amplifier 162 detects and amplifies a signal with the chopping frequency f2 of the second chopper 132. In other words, the second lock-in amplifier 162 extracts only a component that changes at the chopping frequency f2 of the second chopper 132. The effect of the second lock-in amplifier 162 is similar to the effect of the first lock-in amplifier 161.

The signal processing device 165 includes a digital oscilloscope, an analog I/O device, or the like, for example. The signal processing device 165 receives a signal transmitted from each of the first lock-in amplifier 161 and the second lock-in amplifier 162, and forms a signal waveform on the basis of the received signal.

The computer 170 includes a calculation unit 171 and a memory unit 172. The calculation unit 171 calculates the ratio between the reflectance R1 of the infrared light L1 out of the reflected light L4 and the reflectance R2 of the infrared light L2 out of the reflected light L4 (reflectance ratio, R1/R2) on the basis of the signals transmitted from the first lock-in amplifier 161 and the second lock-in amplifier 162 via the signal processing device 165. The memory unit 172 stores the correlation between the reflectance ratio found from a prescribed formula or the like and the resistivity of the semiconductor of the sample 200 (for example, a calibration curve, a correspondence table, etc.) beforehand. The correlation between the reflectance ratio found from a prescribed formula or the like and the resistivity of the semiconductor varies with the semiconductor material. The calculation unit 171 refers to the calculated reflectance ratio (R1/R2) and the correlation stored in the memory unit 172, and reads the resistivity of the semiconductor corresponding to the calculated reflectance ratio (R1/R2). Details of this are described later.

The computer 170 controls the operation of the stage 181.

Next, the operation of the apparatus for testing the resistivity of a semiconductor 100 is further described.

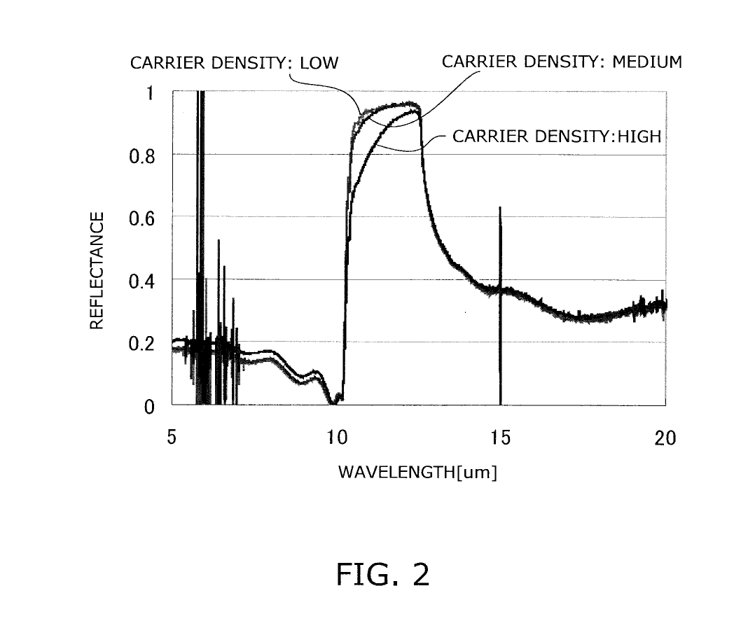

FIG. 2 is a graph illustrating an example of the relationship between the wavelength and the reflectance of reflected light reflected at SiC (silicon carbide).

The infrared light L1 emitted from the first light source 111 passes through the first lens 121, is chopped at the chopping frequency f1 by the first chopper 131, and passes through the first dichroic mirror 141.

The infrared light L2 emitted from the second light source 112 passes through the second lens 122, is chopped at the chopping frequency f2 by the second chopper 132, and is reflected at the second dichroic mirror 142 and the first dichroic mirror 141.

The wavelength λ1 of the infrared light L1 emitted by the first light source 111 is different from the wavelength λ2 of the infrared light L2 emitted by the second light source 112. The chopping frequency f1 of the first chopper 131 is different from the chopping frequency f2 of the second chopper 132. One of the chopping frequency f1 and the chopping frequency f2 is not an integral multiple of the other of the chopping frequency f1 and the chopping frequency f2.

The infrared light L1 that has passed through the first dichroic mirror 141 and the infrared light L2 reflected at the second dichroic mirror 141 are synthesized with each other into infrared light L3, and the infrared light L3 is applied to the prescribed range of the sample 200 coaxially. That is, the infrared light L3 having a plurality of wavelengths is applied to the prescribed range of the sample 200 coaxially. Thereby, the influence of the inclination of the sample 200 and the roughness of the surface of the sample 200 can be suppressed. The infrared light L3 applied to the sample 200 is reflected at the semiconductor of the sample 200. The reflected light L4 reflected at the semiconductor of the sample 200 is reflected at the fourth dichroic mirror 146, and passes through the fourth lens 126 and the fifth lens 127 to be incident on the detector 151.

The detector 151 detects the reflected light L4 reflected at the semiconductor of the sample 200. That is, the reflected light L4 at the semiconductor of the infrared light L3 having a plurality of wavelengths which has been applied to the sample 200 coaxially is detected by one detector (in this example, the detector 151).

Here, it is known that, depending on the semiconductor material, the permittivity is negative in the band between the TO phonon frequency (transverse optical phonon frequency) and the LO phonon frequency (longitudinal optical phonon frequency) and the reflectance is high in the band as compared to semiconductor materials in which phonon absorption does not occur. Such semiconductor materials include SiC (silicon carbide), GaN (gallium nitride), and the like.

The reflectance at the semiconductor of the infrared light L3 depends on the carrier density of the semiconductor in the region irradiated with the infrared light L3. The carrier density of the semiconductor influences the resistivity in the region irradiated with the infrared light L3.

In view of this, the apparatus for testing the resistivity of a semiconductor 100 according to the embodiment makes estimation by separating the reflectance of light with a wavelength that is likely to be influenced by the resistivity and the reflectance of light with a wavelength that is less likely to be influenced by the resistivity. In other words, the apparatus for testing the resistivity of a semiconductor 100 according to the embodiment makes estimation by separating the reflectance of light with a wavelength sensitive to the resistivity (a first wavelength) and the reflectance of light with a wavelength not sensitive to the resistivity (a second wavelength).

As shown in FIG. 2, in SiC, the band of the first wavelength is approximately not less than 10 μm and not more than 12 μm. In SiC, the band of the second wavelength is a band except approximately not less than 10 μm and not more than 12 μm. That is, in the specification of this application, “the first wavelength” refers to a wavelength between the TO phonon frequency (transverse optical phonon frequency) and the LO phonon frequency (longitudinal optical phonon frequency). In the specification of this application, “the second wavelength” refers to a wavelength except between the TO phonon frequency (transverse optical phonon frequency) and the LO phonon frequency (longitudinal optical phonon frequency), that is, a wavelength different from the first wavelength. The band of the first wavelength and the band of the second wavelength vary with the semiconductor material.

When the resistivity of SiC is tested, the wavelength λ1 of the infrared light L1 emitted from the first light source 111 is set to, for example, approximately 12 μm as the first wavelength. When the resistivity of SiC is tested, the wavelength λ2 of the infrared light L2 emitted from the second light source 112 is set to, for example, approximately 14 μm as the second wavelength.

The chopping frequency f1 of the first chopper 131 is set to approximately 30 kHz, for example. The chopping frequency f2 of the second chopper 132 is set to approximately 50 kHz, for example.

The detector 151 outputs a voltage signal corresponding to the intensity of the reflected light L4 having a plurality of wavelengths to the first lock-in amplifier 161 and the second lock-in amplifier 162.

The first lock-in amplifier 161 detects a signal with the chopping frequency f1 (in this example, approximately 30 kHz) of the first chopper 131 out of the signal outputted by the detector 151. Here, the detected signal is a signal regarding light with the first wavelength (in this example, approximately 12 μm) (the infrared light L1). The first lock-in amplifier 161 outputs the detected signal to the computer 170 via the signal processing device 165.

The second lock-in amplifier 162 detects a signal with the chopping frequency f2 (in this example, approximately 50 kHz) of the second chopper 132 out of the signal outputted by the detector 151. Here, the detected signal is a signal regarding light with the second wavelength (in this example, approximately 14 μm) (the infrared light L2). The second lock-in amplifier 162 outputs the detected signal to the computer 170 via the signal processing device 165.

The calculation unit 171 of the computer 170 calculates the ratio between the reflectance R1 of the infrared light L1 out of the reflected light L4 and the reflectance R2 of the infrared light L2 out of the reflected light L4 (reflectance ratio, R1/R2) on the basis of the signals transmitted from the first lock-in amplifier 161 and the second lock-in amplifier 162 via the signal processing device 165. The calculation unit 171 refers to the calculated reflectance ratio (R1/R2) and the correlation stored in the memory unit 172 (for example, a calibration curve, a correspondence table, etc.), and reads the resistivity of the semiconductor corresponding to the calculated reflectance ratio (R1/R2).

By the embodiment, by utilizing the difference between the chopping frequency f1 of the first chopper 131 and the chopping frequency f2 of the second chopper 132, the reflectances of the reflected light L4 having a plurality of wavelengths are measured simultaneously by one detector (in this example, the detector 151). Thereby, the measurement of the reflectances of light having a plurality of wavelengths can be made in a time substantially equal to that of the measurement of the reflectance of light having a single wavelength, and measurement time can be shortened. Furthermore, since the reflected light L4 has a plurality of wavelengths, measurement accuracy can be improved.

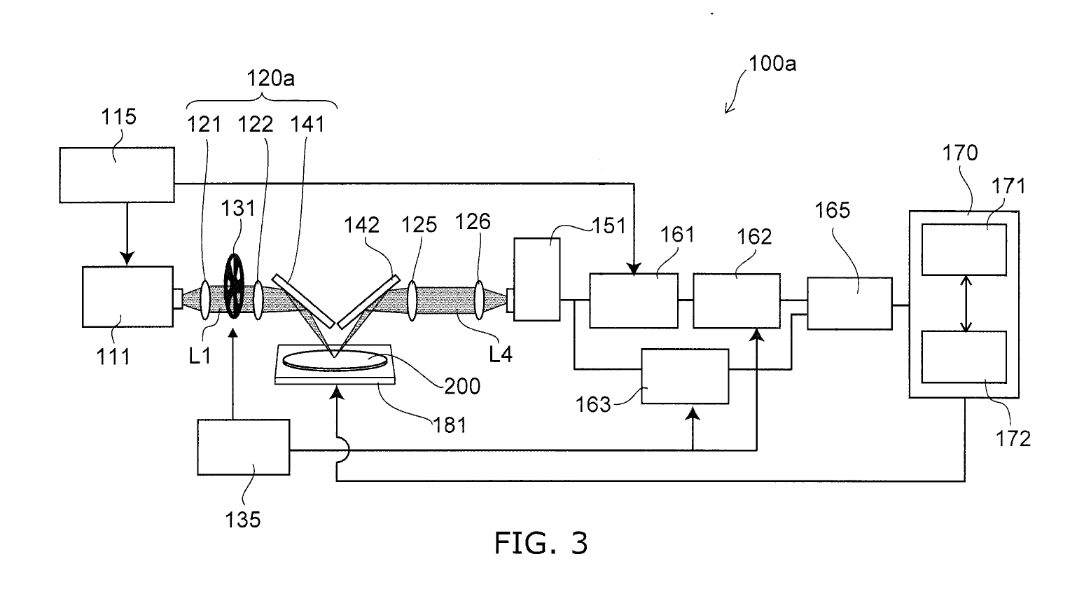

FIG. 3 is a block diagram showing another apparatus for testing the resistivity of a semiconductor according to the embodiment of the invention.

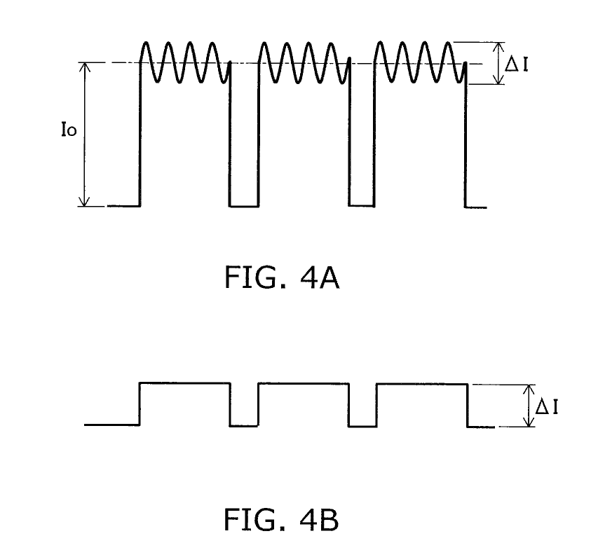

FIG. 4A and FIG. 4B are schematic diagrams showing signals outputted by the detector and the first lock-in amplifier.

FIG. 4A is a schematic diagram showing the signal outputted by the detector. FIG. 4B is a schematic diagram showing the signal outputted by the first lock-in amplifier.

An apparatus for testing the resistivity of a semiconductor 100a shown in FIG. 3 includes the first light source 111, a light source driver 115, the first chopper 131, a chopper driver 135, an irradiation unit 120a, the detector 151, the first lock-in amplifier 161, the second lock-in amplifier 162, a third lock-in amplifier 163, the signal processing device 165, the computer 170, and the stage 181.

The irradiation unit 120a of the apparatus for testing the resistivity of a semiconductor 100a shown in FIG. 3 includes the first lens 121, the second lens 122, and the first dichroic mirror 141. The apparatus for testing the resistivity of a semiconductor 100a shown in FIG. 3 includes the third lens 125, the fourth lens 126, and the second dichroic mirror 142 as appropriate. The installation configuration of the lenses and the dichroic mirrors is not limited to the installation configuration shown in FIG. 3 but may be altered as appropriate. In the apparatus for testing the resistivity of a semiconductor 100a shown in FIG. 3, the first dichroic mirror 141 is not limited to a dichroic mirror, and any mirror capable of reflecting the infrared light L1 may be used, for example. The second dichroic mirror 142 is not limited to a dichroic mirror, and any mirror capable of reflecting the reflected light L4 reflected at the semiconductor of the sample 200 may be used, for example. The apparatus for testing the resistivity of a semiconductor 100a according to the embodiment may not necessarily include the first light source 111 and the second light source 112.

The light source driver 115 modulates the wavelength of the infrared light L1 emitted by the first light source 111. Specifically, the light source driver 115 can sweep the wavelength of the infrared light L1 emitted by the first light source 111 at a frequency f3 higher than the chopping frequency f1 of the first chopper 131 in a relatively wide range. The light source driver 115 transmits to the first lock-in amplifier 161 a signal with the frequency f3 at which the wavelength of the infrared light L1 is swept. The frequency f3 at which the light source driver 115 sweeps the wavelength of the infrared light L1 is of the order of kilohertz (kHz), for example.

The chopper driver 135 controls the chopping frequency f1 of the first chopper 131, and transmits a signal with the chopping frequency f1 (reference signal) to the second lock-in amplifier 162 and the third lock-in amplifier 163. The chopping frequency f1 of the first chopper 131 is approximately 100 Hz or less, for example.

The irradiation unit 120a causes the infrared light L1 emitted from the first light source 111 to be applied to a prescribed range of the sample 200.

Otherwise, the structure is similar to the structure of the apparatus for testing the resistivity of a semiconductor 100 described above in regard to FIG. 1.

Next, the operation of the apparatus for testing the resistivity of a semiconductor 100a is further described.

In the method for testing the resistivity of a semiconductor according to the embodiment, the resistivity of a semiconductor formed on a matrix (for example, a semiconductor wafer) is tested. The wavelength of the infrared light L1 emitted from the first light source 111 is swept by the light source driver 115 at the frequency f3 higher than the chopping frequency f1 of the first chopper 131 in a relatively wide range. As described above in regard to FIG. 2, it is known that, for example in SiC (silicon carbide), GaN (gallium nitride), and the like, the permittivity is negative in the band between the TO phonon frequency (transverse optical phonon frequency) and the LO phonon frequency (longitudinal optical phonon frequency) and the reflectance is high in the band as compared to semiconductor materials in which phonon absorption does not occur.

Thus, the light source driver 115 of the embodiment sweeps the wavelength of the infrared light L1 in a band including a wavelength that is likely to be influenced by the resistivity. In other words, the light source driver 115 of the embodiment sweeps the wavelength of the infrared light L1 in a band including the first wavelength. The band in which the light source driver 115 sweeps the wavelength of the infrared light L1 is approximately not less than 10 μm and not more than 12 μm, for example. The band of the first wavelength is as described above in regard to FIG. 2.

The infrared light L1 emitted from the first light source 111 passes through the first lens 121, is chopped at the chopping frequency f1 by the first chopper 131, and passes through the second lens 122. The infrared light L1 that has passed through the second lens 122 is reflected at the first dichroic mirror 141, and is applied to the prescribed range of the sample 200.

Since the wavelength of the infrared light L1 has been swept by the light source driver 115 as described above, the infrared light L1 emitted from the first light source 111 has a plurality of wavelengths. The infrared light L1 having a plurality of wavelengths is applied to the prescribed range of the sample 200 coaxially. Thereby, the influence of the inclination of the sample 200 and the roughness of the surface of the sample 200 can be suppressed. The infrared light L3 applied to the sample 200 is reflected at the semiconductor of the sample 200. The reflected light L4 reflected at the semiconductor of the sample 200 is reflected at the second dichroic mirror 142, and passes through the third lens 125 and the fourth lens 126 to be incident on the detector 151.

The detector 151 detects the reflected light L4 reflected at the semiconductor of the sample 200. That is, the reflected light L4 at the semiconductor of the infrared light L1 having a plurality of wavelengths which has been applied to the sample 200 coaxially is detected by one detector (in this example, the detector 151).

The signal waveform detected by the detector 151 (the output signal waveform of the detector 151) is as shown in FIG. 4A. The signal waveform shown in FIG. 4A has a change in the reflection intensity ΔI resulting from the wavelength sweeping of the light source driver 115 and the average reflection intensity I₀ in the band of the wavelength sweeping of the light source driver 115. The detector 151 outputs the signal with the waveform shown in FIG. 4A to the first lock-in amplifier 161 and the second lock-in amplifier 162.

The first lock-in amplifier 161 detects a signal with the frequency f3 of the wavelength sweeping of the light source driver 115 out of the signal outputted by the detector 151. In other words, the first lock-in amplifier 161 performs lock-in detection at the frequency f3 of the wavelength sweeping of the light source driver 115. Then, the first lock-in amplifier 161 outputs a signal with the waveform shown in FIG. 4B to the second lock-in amplifier 162.

The second lock-in amplifier 162 detects a signal with the chopping frequency f1 of the first chopper 131 out of the signal outputted by the first lock-in amplifier 161. In other words, the second lock-in amplifier 162 performs lock-in detection at the chopping frequency f1 of the first chopper 131. Thereby, the second lock-in amplifier 162 can acquire the change in the reflection intensity ΔI resulting from the wavelength sweeping of the light source driver 115, and can output the change in the reflection intensity ΔI to the computer 170 via the signal processing device 165.

The third lock-in amplifier 163 detects a signal with the chopping frequency f1 of the first chopper 131 out of the signal outputted by the detector 151. In other words, the third lock-in amplifier 163 performs lock-in detection at the chopping frequency f1 of the first chopper 131. Thereby, the third lock-in amplifier 163 can acquire the average reflection intensity I₀ in the band of the wavelength sweeping of the light source driver 115, and can output the average reflection intensity I₀ to the computer 170 via the signal processing device 165.

The calculation unit 171 of the computer 170 calculates the ratio between the change in the reflection intensity ΔI resulting from the wavelength sweeping of the light source driver 115 and the average reflection intensity I₀ in the band of the wavelength sweeping of the light source driver 115 (intensity ratio; ΔI/I₀) on the basis of the signals transmitted from the second lock-in amplifier 162 and the third lock-in amplifier 163 via the signal processing device 165. The calculation unit 171 refers to the calculated intensity ratio (ΔI/I₀) and the correlation stored in the memory unit 172 (for example, a calibration curve, a correspondence table, etc.), and reads the resistivity of the semiconductor corresponding to the calculated intensity ratio (ΔI/I₀).

In the embodiment, the memory unit 172 stores the correlation between the intensity ratio found from a prescribed formula or the like and the resistivity of the semiconductor of the sample 200 (for example, a calibration curve, a correspondence table, etc.) beforehand.

By the embodiment, by utilizing the difference between the frequency f3 of the wavelength sweeping of the light source driver 115 and the chopping frequency f1 of the first chopper 131, the reflectances of the reflected light L4 having a plurality of wavelengths are measured simultaneously by one detector (in this example, the detector 151). Thereby, the measurement of the reflectances of light having a plurality of wavelengths can be made in a time substantially equal to that of the measurement of the reflectance of light having a single wavelength, and measurement time can be shortened. Furthermore, since the reflected light L4 has a plurality of wavelengths, measurement accuracy can be improved.

In the embodiment, even if neither the chopper 131 nor the chopper driver 135 is provided, the change in the reflection intensity ΔI resulting from the wavelength sweeping of the light source driver 115 can be found based on the signal outputted by the first lock-in amplifier 161 (the signal with the waveform shown in FIG. 4B). On the other hand, the average reflection intensity I₀ in the band of the wavelength sweeping of the light source driver 115 can be found based on the signal outputted by the detector 151 (the signal with the waveform shown in FIG. 4A). Thereby, the calculation unit 171 can read the resistivity of the semiconductor by calculating the intensity ratio (ΔI/I₀) and referring to the calculated intensity ratio (ΔI/I₀) and the correlation stored in the memory unit 172. Hence, the apparatus for testing the resistivity of a semiconductor 100a according to the embodiment may not necessarily include the chopper 131, the chopper driver 135, the second lock-in amplifier 162, and the third lock-in amplifier 163.

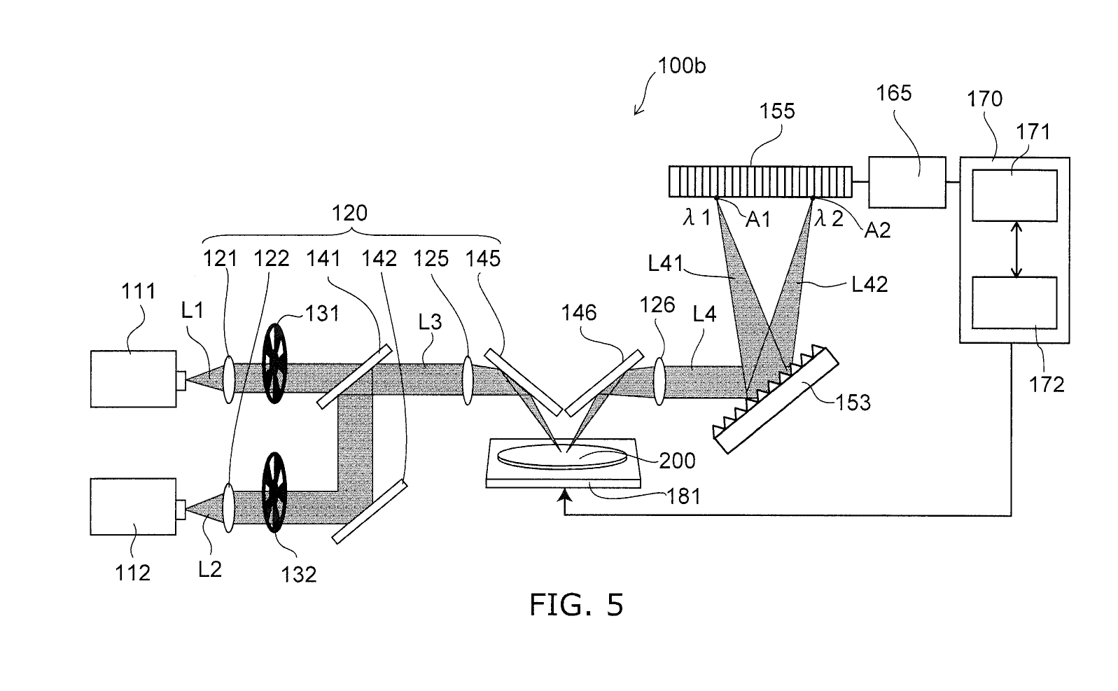

FIG. 5 is a block diagram showing still another apparatus for testing the resistivity of a semiconductor according to the embodiment of the invention.

An apparatus for testing the resistivity of a semiconductor 100b shown in FIG. 5 includes a diffraction grating 153 and a one-dimensional detector 155 in place of the detector 151, the first lock-in amplifier 161, and the second lock-in amplifier 162 in the apparatus for testing the resistivity of a semiconductor 100 shown in FIG. 1. The one-dimensional detector 155 is called a line sensor or the like, for example.

Otherwise, the structure is similar to the structure of the apparatus for testing the resistivity of a semiconductor 100 described above in regard to FIG. 1.

The operation from when the infrared light L1 is emitted from the first light source 111 to when it is reflected at the semiconductor of the sample 200 is as described above in regard to FIG. 1. The operation from when the infrared light L2 is emitted from the second light source 112 to when it is reflected at the semiconductor of the sample 200 is as described above in regard to FIG. 1.

Subsequently, the reflected light L4 reflected at the semiconductor of the sample 200 is reflected at the fourth dichroic mirror 146, and passes through the fourth lens 126 to be incident on the diffraction grating 153. The diffraction grating 153 can condense the reflected light L4 to certain positions on the one-dimensional detector 155 in accordance with the wavelength by utilizing the diffraction of light. The one-dimensional detector 155 can detect the intensity of the reflected light L4 condensed by the diffraction grating 153. Here, positions in the linear reflected light L4 and positions in the one-dimensional detector 155 correspond to each other. Therefore, the one-dimensional detector 155 can detect each intensity corresponding to each position of the linear reflected light L4.

A first reflected light L41 including the wavelength λ1 out of the reflected light L4 is condensed to a first position A1 in the one-dimensional detector 155, for example. On the other hand, a second reflected light L42 including the wavelength λ2 out of the reflected light L4 is condensed to a second position A2 in the one-dimensional detector 155. In other words, the first reflected light L41 including the wavelength λ1 and the second reflected light L42 including the wavelength λ2 are condensed to positions different from each other.

The one-dimensional detector 155 detects the intensities of the reflected light L41 condensed at the first position A1 and the reflected light L42 condensed at the second position A2, and outputs the detected signals to the computer 170 via the signal processing device 165.

The calculation that the computer 170 makes is as described above in regard to FIG. 1.

By the embodiment, by dispersing light using a diffraction grating on the basis of the difference between the wavelength λ1 of the infrared light L1 and the wavelength λ2 of the infrared light L2, the reflectances of the reflected light L4 having a plurality of wavelengths are measured simultaneously by one detector (in this example, the one-dimensional detector 155). Thereby, the measurement of the reflectances of light having a plurality of wavelengths can be made in a time substantially equal to that of the measurement of the reflectance of light having a single wavelength, and measurement time can be shortened. Furthermore, since the reflected light L4 has a plurality of wavelengths, measurement accuracy can be improved.

Next, methods for testing the resistivity of a semiconductor according to the embodiment of the invention are described with reference to the drawings.

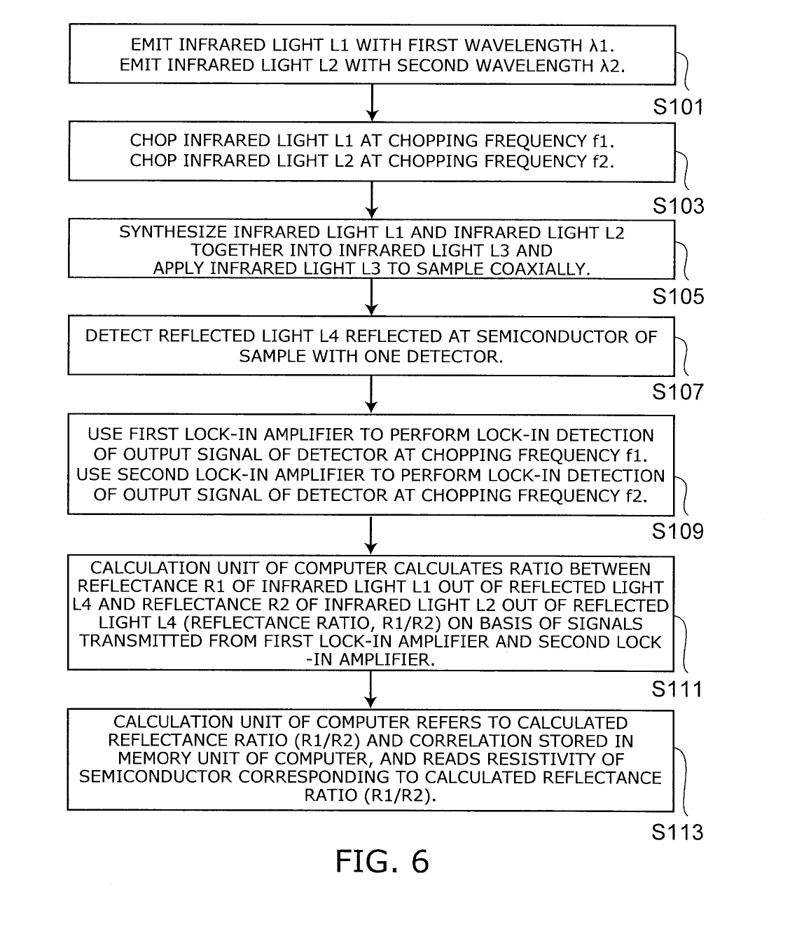

FIG. 6 is a flow chart showing a method for testing the resistivity of a semiconductor according to the embodiment of the invention.

First, the infrared light L1 with the first wavelength λ1 is emitted from the first light source 111 (step S101). Further, the infrared light L2 with the second wavelength λ2 is emitted from the second light source 112 (step S101). Each of the first wavelength λ1 and the second wavelength λ2 is a single wavelength. The wavelength λ2 is different from the wavelength λ1.

Subsequently, the first chopper 131 is used to chop the infrared light L1 emitted by the first light source 111 at the chopping frequency f1 (step S103). Further, the second chopper 132 is used to chop the infrared light L2 emitted by the second light source 112 at the chopping frequency f2 (step S103).

Subsequently, the infrared light L1 and the infrared light L2 are synthesized together into the infrared light L3 (synthetic light), and the infrared light L3 is applied to a prescribed range of the sample 200 coaxially (step S105).

Subsequently, the reflected light L4 reflected at the semiconductor of the sample 200 is detected by one detector 151 (step S107).

Subsequently, the first lock-in amplifier 161 is used to perform lock-in detection in which a signal with the chopping frequency f1 of the first chopper 131 is detected out of the signal outputted by the detector 151 (step S109). Further, the second lock-in amplifier 162 is used to perform lock-in detection in which a signal with the chopping frequency f2 of the second chopper 132 is detected out of the signal outputted by the detector 151 (step S109).

Subsequently, the calculation unit 171 of the computer 170 calculates the ratio between the reflectance R1 of the infrared light L1 out of the reflected light L4 and the reflectance R2 of the infrared light L2 out of the reflected light L4 (reflectance ratio, R1/R2) on the basis of the signals transmitted from the first lock-in amplifier 161 and the second lock-in amplifier 162 (step S111).

Subsequently, the calculation unit 171 of the computer 170 refers to the calculated reflectance ratio (R1/R2) and the correlation stored in the memory unit 172 (for example, a calibration curve, a correspondence table, etc.), and reads the resistivity of the semiconductor corresponding to the calculated reflectance ratio (R1/R2) (step S113).

By the embodiment, by utilizing the difference between the chopping frequency f1 of the first chopper 131 and the chopping frequency f2 of the second chopper 132, the reflectances of the reflected light L4 having a plurality of wavelengths can be measured simultaneously by one detector. Thereby, the measurement of the reflectances of light having a plurality of wavelengths can be made in a time substantially equal to that of the measurement of the reflectance of light having a single wavelength, and measurement time can be shortened. Furthermore, since the reflected light L4 has a plurality of wavelengths, measurement accuracy can be improved.

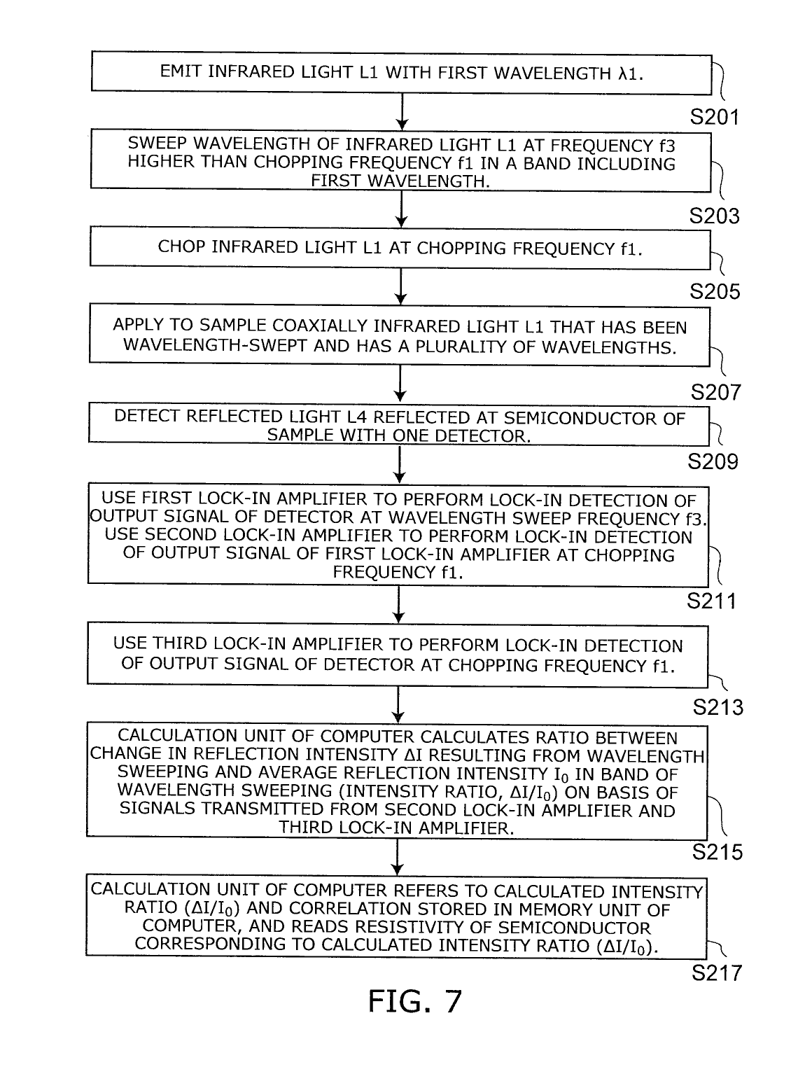

FIG. 7 is a flow chart showing another method for testing the resistivity of a semiconductor according to the embodiment.

First, the infrared light L1 with the wavelength λ1 is emitted from the first light source 111 (step S201).

Subsequently, the wavelength of the infrared light L1 is swept at the frequency f3 higher than the chopping frequency f1 in a band including the first wavelength (step S203).

Subsequently, the first chopper 131 is used to chop the infrared light L1 emitted by the first light source 111 at the chopping frequency f1 (step S205).

Subsequently, the infrared light L1 that has been wavelength-swept and has a plurality of wavelengths is applied to a prescribed range of the sample 200 coaxially (step S207).

Subsequently, the reflected light L4 reflected at the semiconductor of the sample 200 is detected by one detector 151 (step S209).

Subsequently, the first lock-in amplifier 161 is used to perform lock-in detection in which a signal with the frequency f3 of wavelength sweeping is detected out of the signal outputted by the detector 151 (step S211). Further, the second lock-in amplifier 162 is used to perform lock-in detection in which a signal with the chopping frequency f1 of the first chopper 131 is detected out of the signal outputted by the first lock-in amplifier 161 (step S211).

Subsequently, the third lock-in amplifier 163 is used to perform lock-in detection in which a signal with the chopping frequency f1 of the first chopper 131 is detected out of the signal outputted by the detector 151 (step S213).

Subsequently, the calculation unit 171 of the computer 170 calculates the ratio between the change in the reflection intensity ΔI resulting from the wavelength sweeping and the average reflection intensity I₀ in the band of the wavelength sweeping (intensity ratio, ΔI/I₀) on the basis of the signals transmitted from the second lock-in amplifier 162 and the third lock-in amplifier 163 (step S215).

The calculation unit 171 of the computer 170 refers to the calculated intensity ratio (ΔI/I₀) and the correlation stored in the memory unit 172 (for example, a calibration curve, a correspondence table, etc.), and reads the resistivity of the semiconductor corresponding to the calculated intensity ratio (ΔI/I₀).

By the embodiment, by utilizing the difference between the frequency f3 of wavelength sweeping and the chopping frequency f1 of the first chopper 131, the reflectances of the reflected light L4 having a plurality of wavelengths can be measured simultaneously by one detector. Thereby, the measurement of the reflectances of light having a plurality of wavelengths can be made in a time substantially equal to that of the measurement of the reflectance of light having a single wavelength, and measurement time can be shortened. Furthermore, since the reflected light L4 has a plurality of wavelengths, measurement accuracy can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An apparatus for testing the resistivity of a semiconductor configured to test a resistivity of a semiconductor formed on a matrix, the apparatus comprising:
a first chopper configured to chop infrared light with a first wavelength emitted from a first light source at a first chopping frequency, the first wavelength being a wavelength between a transverse optical phonon frequency and a longitudinal optical phonon frequency;
a second chopper configured to chop infrared light with a second wavelength emitted from a second light source at a second chopping frequency, the second wavelength being a wavelength different from the first wavelength;
an irradiation unit configured to cause synthetic light produced by synthesizing the infrared light with the first wavelength and the infrared light with the second wavelength together to be applied to the semiconductor;
a detector configured to detect an intensity of reflected light of the synthetic light reflected at the semiconductor;
a first lock-in amplifier configured to detect a signal with the first chopping frequency out of a signal transmitted from the detector;
a second lock-in amplifier configured to detect a signal with the second chopping frequency out of a signal transmitted from the detector; and
a computer configured to estimate a ratio between a reflectance of the infrared light with the first wavelength out of the reflected light and a reflectance of the infrared light with the second wavelength out of the reflected light on the basis of signals transmitted from the first lock-in amplifier and the second lock-in amplifier.

2. An apparatus for testing the resistivity of a semiconductor configured to test a resistivity of a semiconductor formed on a matrix, the apparatus comprising:
a first chopper configured to chop infrared light with a first wavelength emitted from a first light source at a first chopping frequency, the first wavelength being a wavelength between a transverse optical phonon frequency and a longitudinal optical phonon frequency;
a second chopper configured to chop infrared light with a second wavelength emitted from a second light source at a second chopping frequency, the second wavelength being a wavelength different from the first wavelength;
an irradiation unit configured to cause synthetic light produced by synthesizing the infrared light with the first wavelength and the infrared light with the second wavelength together to be applied to the semiconductor;
a diffraction grating configured to disperse reflected light of the synthetic light reflected at the semiconductor;
a one-dimensional detector configured to detect an intensity of the dispersed reflected light; and
a computer configured to estimate a ratio between a reflectance of the infrared light with the first wavelength out of the reflected light and a reflectance of the infrared light with the second wavelength out of the reflected light on the basis of a signal transmitted from the one-dimensional detector.

3. An apparatus for testing the resistivity of a semiconductor configured to test a resistivity of a semiconductor formed on a matrix, the apparatus comprising:
an irradiation unit configured to cause infrared light emitted from a light source to be applied to the semiconductor;
a light source driver configured to sweep a wavelength of the infrared light in a band including a first wavelength that is a wavelength between a transverse optical phonon frequency and a longitudinal optical phonon frequency;
a detector configured to detect an intensity of reflected light of the infrared light reflected at the semiconductor;
a first lock-in amplifier configured to detect a signal with a wavelength sweep frequency of the light source driver out of a signal transmitted from the detector; and
a computer configured to estimate a ratio between a change in a reflection intensity resulting from the sweeping of the light source driver and an average reflection intensity in a wavelength band of the sweeping of the light source driver on the basis of a signal transmitted from the first lock-in amplifier.

4. The apparatus for testing the resistivity of a semiconductor according to claim 3, further comprising:
a chopper configured to chop the infrared light emitted from the light source at a chopping frequency lower than the wavelength sweep frequency;
a second lock-in amplifier configured to detect a signal with the chopping frequency out of a signal transmitted from the first lock-in amplifier; and
a third lock-in amplifier configured to detect a signal with the chopping frequency out of a signal transmitted from the detector,
the computer being configured to estimate a ratio between a change in a reflection intensity resulting from the sweeping of the light source driver and an average reflection intensity in a wavelength band of the sweeping of the light source driver on the basis of signals transmitted from the second lock-in amplifier and the third lock-in amplifier.

5. The apparatus for testing the resistivity of a semiconductor according to claim 1, wherein
phonon absorption occurs in the semiconductor and
a reflectance in a band between a transverse optical phonon frequency and a longitudinal optical phonon frequency is high as compared to a semiconductor in which the phonon absorption does not occur.

6. The apparatus for testing the resistivity of a semiconductor according to claim 2, wherein
phonon absorption occurs in the semiconductor and
a reflectance in a band between a transverse optical phonon frequency and a longitudinal optical phonon frequency is high as compared to a semiconductor in which the phonon absorption does not occur.

7. The apparatus for testing the resistivity of a semiconductor according to claim 3, wherein
phonon absorption occurs in the semiconductor and
a reflectance in a band between a transverse optical phonon frequency and a longitudinal optical phonon frequency is high as compared to a semiconductor in which the phonon absorption does not occur.

8. The apparatus for testing the resistivity of a semiconductor according to claim 1, wherein the second wavelength is a wavelength except between the transverse optical phonon frequency and the longitudinal optical phonon frequency.

9. The apparatus for testing the resistivity of a semiconductor according to claim 2, wherein the second wavelength is a wavelength except between the transverse optical phonon frequency and the longitudinal optical phonon frequency.

10. The apparatus for testing the resistivity of a semiconductor according to claim 1, wherein one of the first chopping frequency and the second chopping frequency is a frequency of a multiple different from an integral multiple of the other of the first chopping frequency and the second chopping frequency.

11. The apparatus for testing the resistivity of a semiconductor according to claim 2, wherein one of the first chopping frequency and the second chopping frequency is a frequency of a multiple different from an integral multiple of the other of the first chopping frequency and the second chopping frequency.

12. The apparatus for testing the resistivity of a semiconductor according to claim 1, wherein the synthetic light having the first wavelength and the second wavelength is applied to the semiconductor coaxially.

13. The apparatus for testing the resistivity of a semiconductor according to claim 2, wherein the synthetic light having the first wavelength and the second wavelength is applied to the semiconductor coaxially.

14. The apparatus for testing the resistivity of a semiconductor according to claim 1, wherein
the first wavelength is a single wavelength and
the second wavelength is a single wavelength.

15. The apparatus for testing the resistivity of a semiconductor according to claim 2, wherein
the first wavelength is a single wavelength and
the second wavelength is a single wavelength.

16. A method for testing the resistivity of a semiconductor for testing a resistivity of a semiconductor formed on a matrix, the method comprising:
emitting infrared light with a first wavelength from a first light source and chopping the infrared light with the first wavelength at a first chopping frequency, the first wavelength being a wavelength between a transverse optical phonon frequency and a longitudinal optical phonon frequency;
emitting infrared light with a second wavelength from a second light source and chopping the infrared light with the second wavelength at a second chopping frequency, the second wavelength being a wavelength different from the first wavelength;
applying synthetic light produced by synthesizing the infrared light with the first wavelength and the infrared light with the second wavelength together to the semiconductor;
using a detector to detect an intensity of reflected light of the synthetic light reflected at the semiconductor;
using a first lock-in amplifier to detect a signal with the first chopping frequency out of a signal transmitted from the detector;
using a second lock-in amplifier to detect a signal with the second chopping frequency out of a signal transmitted from the detector; and
estimating a ratio between a reflectance of the infrared light with the first wavelength out of the reflected light and a reflectance of the infrared light with the second wavelength out of the reflected light on the basis of signals transmitted from the first lock-in amplifier and the second lock-in amplifier.

17. The method for testing the resistivity of a semiconductor according to claim 16, wherein the second wavelength is a wavelength except between the transverse optical phonon frequency and the longitudinal optical phonon frequency.

18. The method for testing the resistivity of a semiconductor according to claim 16, wherein one of the first chopping frequency and the second chopping frequency is a frequency of a multiple different from an integral multiple of the other of the first chopping frequency and the second chopping frequency.

19. A method for testing the resistivity of a semiconductor for testing a resistivity of a semiconductor formed on a matrix, the method comprising:
applying infrared light emitted from a light source to the semiconductor;
using a light source driver to sweep a wavelength of the infrared light in a band including a first wavelength that is a wavelength between a transverse optical phonon frequency and a longitudinal optical phonon frequency;
using a detector to detect an intensity of reflected light of the infrared light reflected at the semiconductor;
using a first lock-in amplifier to detect a signal with a wavelength sweep frequency of the light source driver out of a signal transmitted from the detector; and
using a computer to estimate a ratio between a change in a reflection intensity resulting from the sweeping of the light source driver and an average reflection intensity in a wavelength band of the sweeping of the light source driver on the basis of a signal transmitted from the first lock-in amplifier.

20. The method for testing the resistivity of a semiconductor according to claim 19, further comprising:
chopping the infrared light emitted from the light source at a chopping frequency lower than the wavelength sweep frequency;
using a second lock-in amplifier to detect a signal with the chopping frequency out of a signal transmitted from the first lock-in amplifier; and
using a third lock-in amplifier to detect a signal with the chopping frequency out of a signal transmitted from the detector,
the computer being configured to estimate a ratio between a change in a reflection intensity resulting from the sweeping of the light source driver and an average reflection intensity in a wavelength band of the sweeping of the light source driver on the basis of signals transmitted from the second lock-in amplifier and the third lock-in amplifier.
